(19) United States
(12) Patent Application Publication
(10) Pub. No.: US 2023/0247820 A1
(43) Pub. Date: Aug. 3, 2023

(54) SEMICONDUCTOR-ELEMENT-INCLUDING MEMORY DEVICE

(71) Applicant: Unisantis Electronics Singapore Pte. Ltd., Singapore (SG)

(72) Inventors: Masakazu KAKUMU, Tokyo (JP); Koji SAKUI, Tokyo (JP); Nozomu HARADA, Tokyo (JP)

(21) Appl. No.: 18/162,446

(22) Filed: Jan. 31, 2023

(30) Foreign Application Priority Data
Feb. 1, 2022 (WO) PCT/JP2022/03747

(51) Int. Cl. H10B 12/00

(52) U.S. Cl. CPC H10B 12/20

(57) ABSTRACT

On a substrate, a first semiconductor layer 1 is formed; from a portion of the layer 1, a first impurity layer 3 extends vertically, and a second semiconductor layer 4 is disposed on the layer 3; side walls of the layers 3 and 4 and the layer 1 are covered with a first gate insulating layer 2; in the resultant grooves, a first gate conductor layer 22 and a second insulating layer 6 are disposed; over the second semiconductor layer 4, layers are disposed that are a third semiconductor layer 8, an n+ layer 7a connecting to a source line SL and an n+ layer 7b connecting to a bit line BL that are disposed on both sides of the layer 8, a second gate insulating layer 9 formed so as to cover the layer 8, and a second gate conductor layer 10 connecting to a word line WL.

### CROSS REFERENCE TO RELATED APPLICATIONS

This application claims priority to PCT/JP2022/003747, filed Feb. 1, 2022, the entire content of which is incorporated herein by reference.

### BACKGROUND OF THE INVENTION

### 1. Field of the Invention

The present invention relates to a semiconductor-element-including memory device.

### 2. Description of the Related Art

In recent years, in development of the LSI (Large Scale Integration) technology, there has been a demand for memory elements having a higher degree of integration, higher performance, lower power consumption, and more functions.

In the ordinary planar MOS transistor, the channel extends, along the upper surface of the semiconductor substrate, in the horizontal direction. By contrast, the channel of the SGT extends in a direction perpendicular to the upper surface of the semiconductor substrate (refer to, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, the SGT enables, compared with the planar MOS transistor, an increase in the density of the semiconductor device. Use of this SGT as a select transistor enables a higher degree of integration in, for example, a DRAM (Dynamic Random Access Memory, refer to, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) to which a capacitor is connected, a PCM (Phase Change Memory, refer to, for example, H. S. Philip Wong, S. Raoux, S. Kim, Jiale Liang, J. R. Reifenberg, B. Rajendran, M. Asheghi and K. E. Goodson: “Phase Change Memory, “Proceeding of IEEE, Vol. 98, No 12, December, pp2b012b27 (2010)) to which a resistance change element is connected, an RRAM (Resistive Random Access Memory, refer to, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3 V”, IEDM (2007)), and an MRAM (Magneto-resistive Random Access Memory, refer to, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) in which a current is used to change the orientation of the magnetic spin to change the resistance. In addition, there are a capacitor-less DRAM memory cell constituted by a single MOS transistor (refer to M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)), and a DRAM memory cell having two groove portions for storing carriers and two gate electrodes (refer to Md. Hasan Raza Ansari, Nupur Navlakha, Jae Yoon Lee, Seongjae Cho, “Double-Gate Junctionless 1T DRAM With Physical Barriers for Retention Improvement”, IEEE Trans, on Electron Devices vol. 67, pp. 1471-1479 (2020)), for example. However, capacitor-less DRAMs are considerably affected by, in the floating bodies, coupling of gate electrodes due to word lines and the voltage margin is not sufficiently provided, which has been a problem. Furthermore, when the substrate is fully depleted, the problem is aggravated. This application relates to a semiconductor-element-including memory device that does not include resistance change elements or capacitors and can be constituted by a MOS transistor alone.

### SUMMARY OF THE INVENTION

In a memory device that is a capacitor-less single-transistor DRAM (gain cell), capacitive coupling between the word line and the body including an element in a floating state is strong; at the time of reading or writing of data, a change in the potential of the word line is transmitted directly as noise to the semiconductor-substrate body, which has been problematic. This causes problems of erroneous reading or erroneous writing of storage data and makes it difficult to put the capacitor-less single-transistor DRAM into practical use. The above-described problems need to be addressed and DRAM memory cells need to have an increased density.

In order to address such problems, a semiconductor-element-including memory device according to an embodiment of the present invention includes

a substrate;

a first semiconductor region disposed on the substrate;

a first impurity region disposed on a portion of a surface of the first semiconductor region and including at least partially a pillar-shaped portion;

a second semiconductor region being in contact with the pillar-shaped portion of the first impurity region and extending in a vertical direction;

a first insulating layer covering a portion of the first semiconductor region and a portion of the first impurity region;

a first gate insulating layer being in contact with the first insulating layer and surrounding the first impurity region and the second semiconductor region;

a first gate conductor layer being in contact with the first insulating layer and the first gate insulating layer;

a second insulating layer formed so as to be in contact with the first gate conductor layer and the first gate insulating layer;

a third semiconductor region being in contact with the second semiconductor region;

a second gate insulating layer surrounding a portion or entirety of an upper portion of the third semiconductor region;

a second gate conductor layer covering a portion or entirety of an upper portion of the second gate insulating layer;

a second impurity region and a third impurity region being disposed outside of ends of the second gate conductor layer and being in contact with, in a horizontal direction in which the third semiconductor region extends, side surfaces of the third semiconductor region;

a first wiring conductor layer connecting to the second impurity region;

a second wiring conductor layer connecting to the third impurity region;

a third wiring conductor layer connecting to the second gate conductor layer; and

a fourth wiring conductor layer connecting to the first gate conductor layer, to form a memory cell (first invention).

In the first invention, the first wiring conductor layer connecting to the second impurity region is a source line, the second wiring conductor layer connecting to the third impurity region is a bit line, the third wiring conductor layer connecting to the second gate conductor layer is a word line, the fourth wiring conductor layer connecting to the first gate conductor layer is a plate line, and the memory device is configured to apply voltages to the source line, the bit line, the plate line, and the word line to perform memory writing or erasing (second invention).

In the first invention, a work function of the first gate conductor layer is different from a work function of the second gate conductor layer (third invention).

In the third invention, the majority carrier of the first impurity region is electrons, the majority carrier of the second semiconductor region is holes, and the work function of the first gate conductor layer is higher than the work function of the second gate conductor layer (fourth invention).

In the third invention, the majority carrier of the first impurity region is holes, the majority carrier of the second semiconductor region is holes, and the work function of the first gate conductor layer is lower than the work function of the second gate conductor layer (fifth invention).

In the first invention, the majority carrier of the first impurity region is different from a majority carrier of the first semiconductor region (sixth invention).

In the first invention, the majority carrier of the second semiconductor region is the same as a majority carrier of the first semiconductor region (seventh invention).

In the first invention, majority carriers of the second impurity region and the third impurity region are the same as the majority carrier of the first impurity region (eighth invention).

In the first invention, the first impurity region has a lower concentration than the second impurity region and the third impurity region (ninth invention).

In the first invention, a vertical distance from a bottom portion of the third semiconductor region to an upper portion of the first impurity region is shorter than a vertical distance from a bottom portion of the third semiconductor region to a bottom portion of the first gate conductor layer (tenth invention).

In the second invention, a source-line contact hole for connection between the source line and the second impurity region and the first wiring conductor layer are shared by adjacent memory cells (eleventh invention).

In the second invention, a bit-line contact hole for connection between the bit line and the third impurity region and the second wiring conductor layer are shared by adjacent memory cells (twelfth invention).

In the first invention, a fourth insulating layer in contact with the first gate conductor layer divides the first gate conductor layer into two layers, the two layers are individually connected to a first plate line and a second plate line, and the first plate line and the second plate line are configured to be independently subjected to application of voltages (thirteenth invention).

In the thirteenth invention, the semiconductor-element-including memory device includes a plurality of memory cells in contact with the first plate line and a plurality of memory cells in contact with the second plate line, wherein each of the memory cells is not in contact with both of the first plate line and the second plate line (fourteenth invention).

In the first invention, the first impurity region has a bottom portion positioned deeper than a bottom portion of the first insulating layer, and the first impurity region is shared by a plurality of memory cells (fifteenth invention).

In the first invention, the first impurity region is shared by a plurality of memory cells and the plurality of memory cells are configured to simultaneously perform an erase operation (sixteenth invention).

In the twelfth invention, the semiconductor-element-including memory device includes a fifth wiring conductor layer connecting to the first impurity region, wherein the fifth wiring conductor layer is a control line and is configured to be subjected to application of a desired voltage (seventeenth invention).

In the first invention, the memory device is configured to control voltages applied to the first wiring conductor layer, the second wiring conductor layer, the third wiring conductor layer, and the fourth wiring conductor layer to perform an operation of using a current flowing between the second impurity region and the third impurity region to cause an impact ionization phenomenon or using a gate induced drain leakage current, to generate an electron group and a hole group in the third semiconductor region and the second semiconductor region, an operation of discharging, of the generated electron group and hole group, the electron group or hole group serving as a minority carrier in the third semiconductor region and the second semiconductor region, and an operation of causing a portion or entirety of the electron group or hole group serving as a majority carrier in the third semiconductor region and the second semiconductor region to remain in the third semiconductor region and the second semiconductor region, to perform a memory write operation, and

the memory device is configured to control voltages applied to the first wiring conductor layer, the second wiring conductor layer, the third wiring conductor layer, and the fourth wiring conductor layer to remove, from at least one of the first impurity region, the second impurity region, or the third impurity region, the electron group or hole group remaining and serving as a majority carrier in the second semiconductor region or the third semiconductor region by recombination with a majority carrier of the first impurity region, the second impurity region, or the third impurity region, to perform a memory erase operation (eighteenth invention).

### BRIEF DESCRIPTION OF THE DRAWINGS

FIG. 1 illustrates a sectional structure of a semiconductor-element-including memory device according to a first embodiment.

FIGS. 2A, 2B, and 2C are explanatory views of the write operation, storage of carriers immediately after the operation, and the cell current in the semiconductor-element-including memory device according to the first embodiment.

FIGS. 3A, 3B, and 3C are explanatory views of storage of hole carriers immediately after the write operation, the erase operation, and the cell current in the semiconductor-element-including memory device according to the first embodiment.

FIGS. 4AA, 4AB, and 4AC are explanatory views of a method for producing the memory device according to the first embodiment.

FIGS. 4BA, 4BB, and 4BC are explanatory views of a method for producing the memory device according to the first embodiment.

FIGS. 4CA, 4CB, and 4CC are explanatory views of a method for producing the memory device according to the first embodiment.

FIGS. 4DA, 4DB, and 4DC are explanatory views of a method for producing the memory device according to the first embodiment.

FIGS. 4EA, 4EB, and 4EC are explanatory views of a method for producing the memory device according to the first embodiment.

FIGS. 4FA, 4FB, and 4FC are explanatory views of a method for producing the memory device according to the first embodiment.

FIGS. 4GA, 4GB, and 4GC are explanatory views of a method for producing the memory device according to the first embodiment.

FIGS. 4HA, 4HB, and 4HC are explanatory views of a method for producing the memory device according to the first embodiment.

FIGS. 4IA, 4IB, and 4IC are explanatory views of a method for producing the memory device according to the first embodiment.

FIGS. 5AA, 5AB, and 5AC illustrate a planar structure and sectional structures of a semiconductor-element-including memory device according to a second embodiment.

FIGS. 5BA, 5BB, and 5BC are explanatory views of a process in production of the memory device according to the second embodiment.

FIGS. 6A and 6B illustrate sectional structures of a semiconductor-element-including memory device according to a third embodiment.

### DESCRIPTION OF THE PREFERRED EMBODIMENTS

Hereinafter, semiconductor-element-including memory devices according to some embodiments of the present invention will be described in terms of the structures, the driving modes, and the behaviors of stored carriers with reference to the drawings.

### First Embodiment

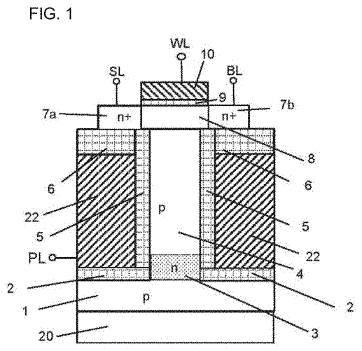

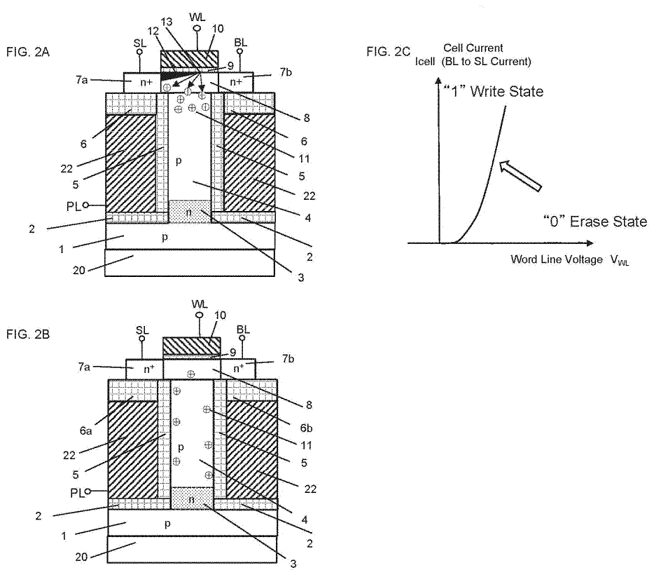

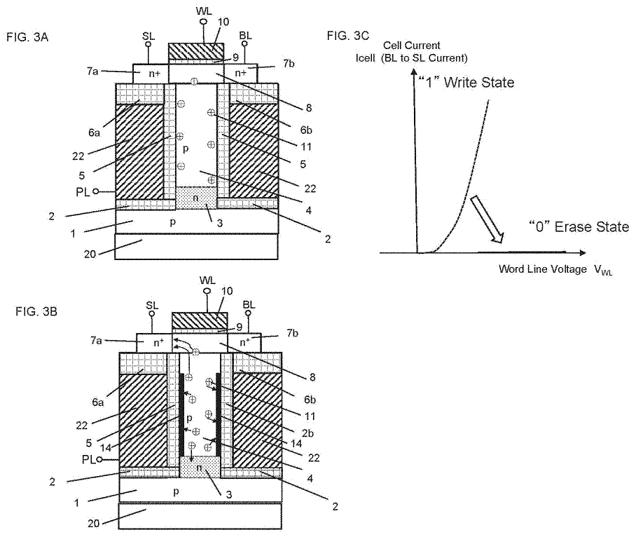

Referring to FIGS. 1 to 3C, a semiconductor-element-including memory cell according to a first embodiment of the present invention will be described in terms of the structure and the operation mechanisms. Referring to FIG. 1, the semiconductor-element-including memory according to this embodiment will be described in terms of the cell structure. Referring to FIGS. 2A to 2C, the semiconductor-element-including memory will be described in terms of the writing mechanism and the behavior of carriers. Referring to FIGS. 3A to 3C, the data erasing mechanism will be described.

FIG. 1 illustrates a vertical sectional structure of the semiconductor-element-including memory according to the first embodiment of the present invention. On a substrate 20 (serving as an example of “substrate” in Claims), a p layer 1 (serving as an example of “first semiconductor region” in Claims) is disposed and made of silicon containing an acceptor impurity and having a p conductivity type. A semiconductor includes an n layer 3 (serving as an example of “first impurity region” in Claims) standing from the surface of the p layer 1 in the vertical direction, having a pillar shape, and containing a donor impurity; and a p layer 4 (serving as an example of “second semiconductor region” in Claims) is disposed on the n layer 3, contains an acceptor impurity, and has a pillar shape. A first insulating layer 2 (serving as an example of “first insulating layer” in Claims) covers a portion of the p layer 1 and a portion of the n layer 3; and a first gate insulating layer 5 (serving as an example of “first gate insulating layer” in Claims) covers a portion of the p layer 4. A first gate conductor layer 22 (serving as an example of “first gate conductor layer” in Claims) is in contact with the first insulating layer 2 and the first gate insulating layer 5. A second insulating layer 6 (serving as an example of “second insulating layer” in Claims) is in contact with the gate insulating layer 5 and the gate conductor layer 22. A p layer 8 (serving as an example of “third semiconductor region” in Claims) is in contact with the p layer 4 and contains an acceptor impurity.

On a side of the p layer 8, an n+ layer 7a (serving as an example of “second impurity region” in Claims) is disposed and contains a donor impurity at a high concentration (hereafter, semiconductor regions containing donor impurities at high concentrations will be referred to as “n+ layers”). On the other side opposite from the n+ layer 7a, an n+ layer 7b (serving as an example of “third impurity region” in Claims) is disposed.

On the upper surface of the p layer 8, a second gate insulating layer 9 (serving as an example of “second gate insulating layer” in Claims) is disposed. The gate insulating layer 9 is disposed in contact with or near the n+ layers 7a and 7b. On a side of the gate insulating layer 9 opposite from the semiconductor layer 8, a second gate conductor layer 10 (serving as an example of “second gate conductor layer” in Claims) is disposed in contact with the gate insulating layer 9, the second gate conductor layer 10 having a work function lower than the work function of the first gate conductor layer 22.

Thus, the substrate 20, the p layer 1, the insulating layer 2, the gate insulating layer 5, the gate conductor layer 22, the insulating layer 6, the n layer 3, the p layer 4, the n+ layer 7a, the n+ layer 7b, the p layer 8, the gate insulating layer 9, and the gate conductor layer 10 constitute a semiconductor-element-including memory device. The n+ layer 7a connects to a source line SL (serving as an example of “source line” in Claims) serving as the first wiring conductive layer; the n+ layer 7b connects to a bit line BL (serving as an example of “bit line” in Claims) serving as the second wiring conductive layer; the gate conductor layer 10 connects to a word line WL (serving as an example of “word line” in Claims) serving as the third wiring conductive layer; and the gate conductor layer 22 connects to a plate line PL (serving as an example of “plate line” in Claims) serving as the fourth wiring conductive layer. The potentials at the source line, the bit line, the plate line, and the word line are controlled to thereby perform memory operations. Hereafter, such a memory device will be referred to as the dynamic flash memory.

In the memory device according to this embodiment, on the substrate 20, such a dynamic flash memory cell is disposed alone or such a plurality of dynamic flash memory cells are arranged two-dimensionally.

For FIG. 1, the p layer 1 has been described as a p-type semiconductor; its impurity concentration may have a profile. The n layer 3, the p layer 4, and the p layer 8 may have impurity concentrations having profiles. For the p layer 4 and the p layer 8, the impurity concentrations and profiles may be independently set. In plan view, the section of the p layer 4 may have the same shape as in the connection surface of the p layer 4 to the p layer 8. LDDs (Lightly Doped Drains) may be disposed between the p layer 8 and the n+ layers 7a and 7b.

When the n+ layer 7a and the n+ layer 7b are formed as p+ layers in which holes serve as the majority carriers (hereafter, semiconductor regions containing acceptor impurities at high concentrations will be referred to as “p+ layers”), the p layer 1, the p layer 4, the p layer 8 are made of n-type semiconductors, the n layer 3 is made of a p-type semiconductor, the gate conductor layer 22 is made of a material having a lower work function than the work function of the gate conductor layer 10, and the operation of the dynamic flash memory is performed with the carriers for writing being electrons.

In FIG. 1, the first semiconductor layer 1 is made of a p-type semiconductor. Alternatively, even when the substrate 20 employed is an n-type semiconductor substrate, a p-well is formed as the first semiconductor layer 1, and a memory cell according to the present invention is disposed, the operation of the dynamic flash memory is performed.

In FIG. 1, the insulating layer 2 and the gate insulating layer 5 are illustrated as different layers, but may alternatively be formed as a single layer. Hereafter, the insulating layer 2 and the gate insulating layer 5 may also be collectively referred to as the gate insulating layer 5.

In FIG. 1, the third semiconductor layer 8 is made of a p-type semiconductor; however, depending on the majority carrier concentration of the p layer 4, the thickness of the third semiconductor layer 8, the material and thickness of the gate insulating layer 9, and the material of the gate conductor layer 10, the third semiconductor layer 8 may be of any type among a p-type, an n-type, and an i-type.

In FIG. 1, the bottom portion of the p layer 8 and the upper surface of the insulating layer 6 are illustrated at the same level; however, as long as the p layer 4 and the p layer 8 are in contact with each other and the bottom portion of the p layer 4 is deeper than the bottom portion of the insulating layer 6, the interface between the p layer 4 and the p layer 8 is not necessarily at the same level as the upper surface of the insulating layer 6.

For the substrate 20, any material such as an insulator, a semiconductor, or a conductor may be used as long as it supports the p layer 1.

As long as the gate conductor layer 22 is configured to change, via the insulating layer 2 or the gate insulating layer 5, the potential of a portion of the memory cell and has a work function different from that of the gate conductor layer 10, the gate conductor layer 22 may be a semiconductor layer doped at a high concentration or a conductor layer.

The first to fourth wiring conductive layers may be formed as multilayers unless being in contact with each other.

In FIG. 1, the bottom portion of the n layer 3 and the bottom portion of the gate insulating layer 2 are illustrated at the same level; however, the bottom portions are not necessarily at the same level as long as the n layer 3 is in contact with both of the p layer 1 and the gate insulating layer 2.

For the gate insulating layers 5 and 10, any insulating films used in ordinary MOS processes can be used, such as SiO₂ films, SiON films, HfSiON films, or SiO₂/SiN laminated films.

FIG. 1 illustrates a MOSFET in which the gate conductor layer 10 has a planar structure; alternatively, the gate conductor layer 10 may have a fin structure more suitable for achieving an increased density or may have a bent gate-electrode structure such as the trench structure. Similarly, the gate conductor layer 22 does not necessarily have a planar structure.

As long as the first gate conductor layer 22 is configured to change, via the gate insulating layer 5, or the second gate conductor layer 10 is configured to change, via the gate insulating layer 9, the potential of a portion of the memory cell, the layers may be made of metals such as W, Pd, Ru, Al, TiN, TaN, or WN, nitrides of metals, or alloys of the metals (including silicide), may have laminated structures such as TiN/W/TaN, or may be formed of semiconductors doped at high concentrations.

For FIG. 1, the memory cell has been described as having a vertical sectional structure that is rectangular; however, the vertical sectional structure may be trapezoidal or polygonal, or, in plan view, the p layer 4 may have a circular section.

In FIG. 1, the first gate conductor layer 22 may surround, in plan view, the entirety of the p layer 4 or may cover a portion of the p layer 4. The first gate conductor layer 22 may be divided, in plan view, into a plurality of layers. The first gate conductor layer 22 may be divided, in the vertical direction, into a plurality of layers. In the sectional structure in FIG. 1, the first gate conductor layer 22 is disposed on both sides of the p layer 4; however, as long as the first gate conductor layer 22 is disposed on one of the sides of the p layer 4, the operation of the dynamic flash memory can also be performed.

Referring to FIG. 2A to 2C, in the dynamic flash memory according to the first embodiment of the present invention, the carrier behavior, storage, and the cell current during the write operation will be described. First, the following case will be described: the majority carriers of the n+ layer 7a and the n+ layer 7b are electrons and, for example, the gate conductor layer 22 connecting to PL is made of p+ poly (hereafter, poly Si containing acceptor impurities at high concentrations will be referred to as “p+ poly”); the gate conductor layer 10 connecting to WL is made of n+ poly (hereafter, poly Si containing donor impurities at high concentrations will be referred to as “n+ poly”); and the third semiconductor layer 8 is made of a p-type semiconductor. As illustrated in FIG. 2A, the MOSFET in this memory cell operates using, as elements, the n+ layer 7a serving as the source, the n+ layer 7b serving as the drain, the gate insulating layer 9, the gate conductor layer 10 serving as the gate, and the p layer 8 serving as the substrate. To the p layer 1, for example, 0 V is applied; to the n+ layer 7a to which the source line SL is connected, for example, 0 V is applied; to the n+ layer 7b to which the bit line BL is connected, for example, 2.0 V is applied; to the gate conductor layer 22 to which the plate line PL is connected, for example, 0 V is applied; to the gate conductor layer 10 to which the word line WL is connected, for example, 2.0 V is applied. Immediately below the gate insulating layer 9 under the gate conductor layer 10, an inversion layer 12 is partly formed and a pinch-off point 13 is present. Thus, the MOSFET including the gate conductor layer 10 operates in the saturation region.

As a result, in the MOSFET including the gate conductor layer 10, the electric field becomes maximum in the boundary region between the pinch-off point 13 and the n+ layer 7b and, in this region, the impact ionization phenomenon occurs. The impact ionization phenomenon causes electrons accelerated from the n+ layer 7a to which the source line SL is connected toward the n+ layer 7b to which the bit line BL is connected to collide with the Si lattice, and the kinetic energy causes generation of electron-hole pairs. The generated holes diffuse, in accordance with their concentration gradient, toward regions having lower hole concentrations. A portion of the generated electrons flow to the gate conductor layer 10, but most of the generated electrons flow to the n+ layer 7b connected to the bit line BL.

Note that, instead of causing the impact ionization phenomenon, a gate induced drain leakage (GIDL) current may be caused to flow to form a hole group (for example, refer to E. Yoshida and T. Tanaka, “A Capacitorless 1T-DARM Technology Using Gate-Induced Drain-Leakage (GIDL) Current for Low-Power and High-Speed Embedded Memory”, IEEE Trans, on Electron Devices vol. 53, pp. 692-697 (2006)).

FIG. 2B illustrates, immediately after the writing, when all the electrodes WL, BL, PL, and SL are at 0 V, hole groups 11 in the p layer 4 and the p layer 8. The generated hole groups 11 are the majority carriers of the p layer 4 and the p layer 8; the concentration of the generated holes is temporarily high in the region of the p layer 8 and the holes move by diffusion, in accordance with the concentration gradient, toward the p layer 4. In addition, the first gate conductor layer 22 is made of p+ poly having a higher work function than the n+ poly, so that the holes are stored at a higher concentration in regions of the p layer 4, the regions being near the first gate insulating layer 5. As a result, the p layer 4 has a hole concentration higher than the hole concentration of the p layer 8. The p layer 4 and the p layer 8 are electrically connected together, so that the p layer 8 substantially serving as a substrate of the MOSFET including the gate conductor layer 10 is charged to a positive bias. The holes within the depletion layer move toward the SL side, the BL side, or the n layer 3, to gradually recombine with electrons; however, the threshold voltage of the MOSFET including the gate conductor layer 10 lowers due to the positive substrate-bias effect caused by holes temporarily stored in the p layer 4 and the p layer 8. Thus, as illustrated in FIG. 2C, the MOSFET including the gate conductor layer 10 to which the word line WL is connected has a lowered threshold voltage. This write state is assigned to logical storage data “1”.

Note that the above-described voltage conditions applied to the bit line BL, the source line SL, the word line WL, and the plate line PL are an example for performing the write operation; with SL being set at 0 V, a combination such as 2.0 V (BL)/0 V (PL)/2.0 V (WL), 1.0 V (BL)/−0.5 V (PL)/1.5 V (WL), or 1.5 V (BL)/−1 V (PL)/2.0 V (WL) can be employed; alternatively, other voltage conditions under which the write operation can be performed may be employed.

FIGS. 2A to 2C have been described using, as an example of the combination of the gate conductor layer 22 and the gate conductor layer 10, the combination of p+ poly (work function: 5.15 eV) and n+ poly (work function: 4.05 eV); alternatively, the combination may be metals, nitrides of metals, alloys of the metals (including silicide), or laminated structures, such as Ni (work function: 5.2 eV) and n+ poly, Ni and W (work function: 4.52 eV), Ni and TaN (work function: 4.0 eV)/W/TiN (work function: 4.7 eV).

In the structure according to this embodiment, in the MOSFET including the gate conductor layer 10 to which the word line WL is connected, the p layer 8 is electrically connected to the p layer 4, so that the capacitance for storing generated holes can be freely changed by adjusting the volume of the p layer 4. Specifically, in order to increase the retention time, for example, the depth of the p layer 4 can be made larger. Thus, the bottom portion of the p layer 4 needs to be positioned deeper than the bottom portion of the p layer 8. In the region where hole carriers are stored, compared with the volume of the p layer 4 and the p layer 8, the area of contact with the n layer 3, the n+ layer 7a, and the n+ layer 7b relating to recombination with electrons can be intentionally reduced, so that recombination with electrons can be suppressed and the retention time of the stored holes can be increased. Furthermore, the gate conductor layer 22 is made of p+ poly, so that the stored holes are stored in the near-interface region of the p layer 4, which is the second semiconductor layer in contact with the first gate insulating layer 5; in addition, holes can be stored in regions apart from the pn junction regions where electron-hole recombination causes loss of data, in other words, contact regions between the n+ layer 7a or the n+ layer 7b and the p layer 8, to thereby achieve stable storage of holes. Thus, for the memory element, the substrate as a whole provides more strongly the substrate-bias effect, the data retention time is increased, and the voltage margin of writing “1” is increased.

Hereinafter, referring to FIGS. 3A to 3C, the erase operation mechanism will be described. FIG. 3A illustrates a state in which, prior to the erase operation, the hole groups 11 generated by impact ionization in the previous cycle are stored in the p layer 4 and the p layer 8 and immediately after all the biases become 0 V. As illustrated in FIG. 3B, during the erase operation, the voltage of the source line SL is set to a negative voltage VERA. The voltage of PL is set to 2 V. VERA is, for example, −0.5 V. As a result, irrespective of the initial potential value of the p layer 8, the PN junction between the p layer 8 and the n+ layer 7a to which the source line SL is connected and which serves as the source is forward biased. As a result, the hole groups 11 generated by impact ionization in the previous cycle and stored in the p layer 4 and the p layer 8 move to the n+ layer 7a connected to the source line. As a result of application of a voltage of 2 V to PL, an inversion layer 14 is formed at the interface between the gate insulating layer 5 and the p layer 4 and in contact with the n layer 3. Thus, the holes stored in the p layer 4 flow from the p layer 4 to the n layer 3 or the inversion layer and undergoes recombination with electrons. As a result, the hole concentrations of the p layer 4 and the p layer 8 decrease with time and the threshold voltage of the MOSFET becomes higher than that at the time of writing of “1”, which is returning to the initial state. Thus, as illustrated in FIG. 3C, the MOSFET including the gate conductor layer 10 to which the word line WL is connected returns to the initial threshold. This erase state of the dynamic flash memory is assigned to logical storage data “0”.

In the structure of this embodiment, at the time of erasing of data, the electron-hole recombination area can be effectively increased, compared with the time of storage of data. Thus, the state in which the logical information data “0” is stable can be supplied in a short time and the operation speed of the dynamic flash memory element is increased.

Note that the above-described voltage conditions applied to the bit line BL, the source line SL, the word line WL, and the plate line PL are an example for performing the erase operation and other voltage conditions under which the erase operation can be performed may be employed. For example, although the example in which the gate conductor layer 22 is biased to 2 V has been described, during erasing, for example, BL is set to 0.2 V, SL is set to 0 V, and the first and second gate conductor layers are biased to 2 V, so that inversion layers in which electrons are the majority carriers can be formed at the interface between the p layer 8 and the gate insulating layer 9 and at the interface between the p layer 4 and the gate insulating layer 2, to increase the electron-hole recombination area; furthermore, a current in which electrons serve as the majority carrier can be caused to flow between BL and SL to thereby intentionally shorten the erase time.

When the film thicknesses of the insulating layer 2 and the insulating layer 6 are made similar to the film thickness of the gate insulating layer 5, application of, for example, 2 V to PL during erasing of data causes the inversion layer 14 to connect together the n+ layer 7a or 7b and the n layer 3, to shorten the time for erasing data. Alternatively, conditions under which an inversion layer 14 is formed at the interface between the gate insulating layer 5 and the p layer 4 and the holes stored thereon and electrons recombine can be employed, for example, with the source line SL being set at 0 V, a combination of 0.5 V (BL)/2 V (PL)/−1 V (WL), 0.5 V (BL)/2 V (PL)/0.5 V (WL), or −0.5 V (BL)/3 V (PL)/0 V (WL); instead of the voltage conditions applied to the bit line BL, the source line SL, the word line WL, and the plate line PL, other operation conditions under which the memory erase operation can be performed may be employed.

In this embodiment, the p layer 8, which is one of the elements of the MOSFET for reading and writing information, is electrically connected to the p layer 1, the n layer 3, and the p layer 4. Furthermore, a voltage can be applied to the gate conductor layer 22. Thus, in the write operation and in the erase operation, phenomena in SOI structures such as, during operation of the MOSFET, instability of the substrate bias in the floating state and full depletion of the semiconductor region under the gate insulating layer 9 do not occur. For this reason, the threshold, the driving current, and the like of the MOSFET are less likely to be affected by the operation state. Thus, for properties of the MOSFET, the thickness, the type of the impurity, the concentration of the impurity, and the profile of the p layer 8, the concentration of the impurity and the profile of the p layer 4, the thickness and the material of the gate insulating layer 9, and the work functions of the gate conductor layers 10 and 22 can be adjusted to thereby set voltages in wide ranges for desired memory operations. In addition, the region under the MOSFET is not fully depleted and a depletion layer extends in the depth direction of the p layer 4, so that the drawback of capacitor-less DRAMs that is, in the floating body, coupling of the gate electrode due to the word line substantially does not affect the MOSFET. Therefore, in this embodiment, the dynamic flash memory can be designed so as to have an increased margin of the operation voltages.

In addition, this embodiment prevents malfunction of memory cells. In operations of memory cells, control of the voltage of the target cell causes unnecessary application of voltages to electrodes of some non-target cells within the cell array to cause malfunction, which is a serious problem (for example, Takashi Ohasawa and Takeshi Hamamoto, “Floating Body Cell —a Novel Body Capacitorless DRAm Cell”, Pan Stanford Publishing (2011)). Specifically, this refers to a phenomenon in which a cell in which “1” has been written is changed to “0” by an operation of another cell, or a cell in which “0” has been written is changed to “1” by an operation of another cell (hereafter, the phenomenon due to this malfunction will be referred to as disturb failure). In this embodiment, when “1” is initially written as data information, the amount of holes stored can be increased, relative to the amount of electron-hole recombination caused by a transistor operation, by adjusting the depth of the p layer 4; thus, even under conditions under which disturb failure occurs in existing memories, change in the threshold of the MOSFET is less likely to be affected and the failure is less likely to be caused. When “0” is initially written as data information, even in the case of unintentional generation of holes by a transistor operation during reading, the holes immediately diffuse through the p layer 4; thus, by similarly setting a large depth of the p layer 4, the change ratio of the hole concentration of the p layer 4 and the p layer 8 as a whole is low; also in this case, the threshold of the MOSFET is less likely to be affected and a lower probability of disturb failure than in the existing memories can be achieved. Therefore, this embodiment provides a structure that is highly resistant to the memory disturb failure.

When data information is “0”, during retention, holes of hole-electron pairs generated in the depletion layer within the cell may be stored in the p layer 8 to change the data from “0” to “1”; however, in the structure according to this embodiment of the present invention, holes are stored at a higher concentration in the p layer 4 and do not considerably affect the change in the hole concentration of the p layer 8 disposed immediately below the MOSFET, so that “0” data information can be retained with stability.

Note that, for the above-described state during retention of data, even when the first gate conductor layer and the second gate conductor layer have the same work function, BL, WL, and SL can be set to 0 V and −0.5 V can be applied to PL to thereby provide similar advantages, which is within the scope of the present invention. However, it is not easy to generate a negative voltage in the inside and to control the negative voltage timely; thus, the use of materials having different work functions for the first gate conductor layer and the second gate conductor layer is an easier method from the viewpoint of the potential control of the electrodes.

As is clear from the structure in FIG. 1, formation of the element structure including the p layer 8, the n+ layers 7a and 7b, the gate insulating layer 9, and the gate conductor layer 10 can be performed not only for the memory cell, but can also be performed for other ordinary MOS circuits including CMOS structures. Thus, the memory cell can be easily combined with existing CMOS circuits.

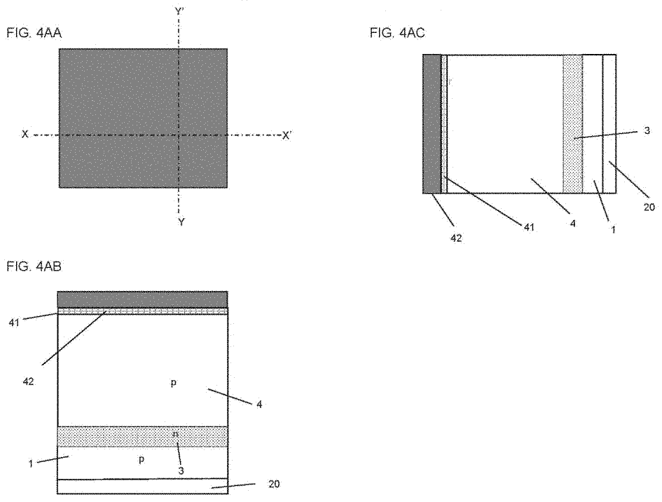

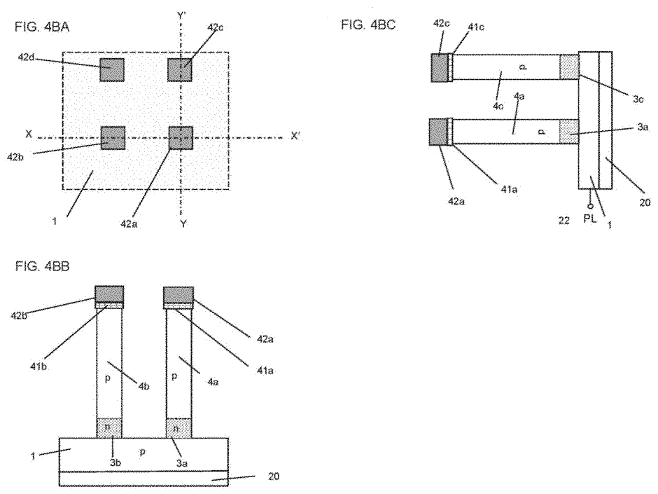

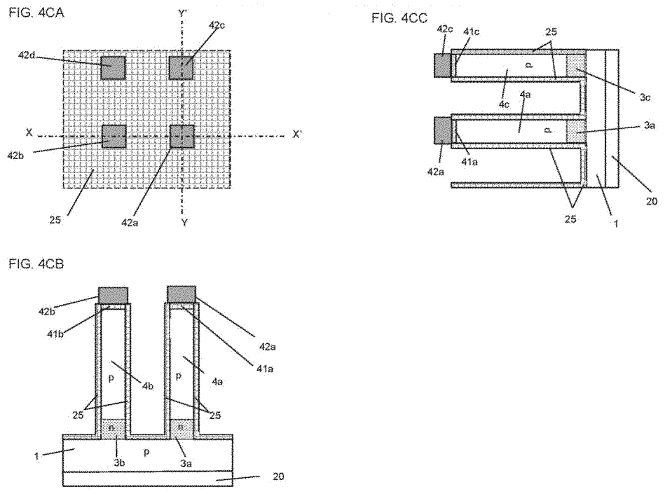

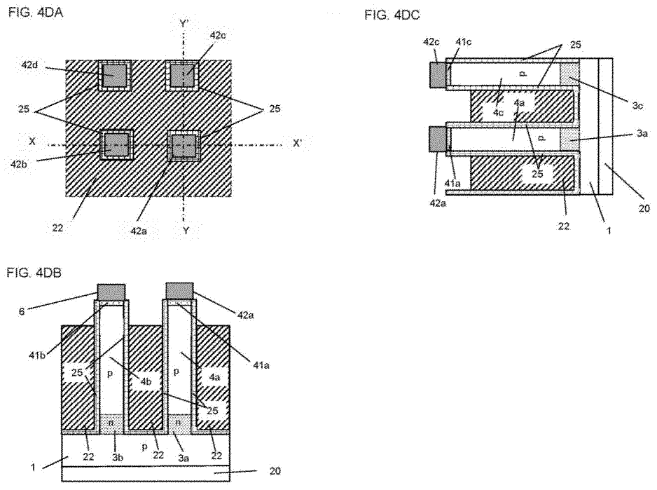

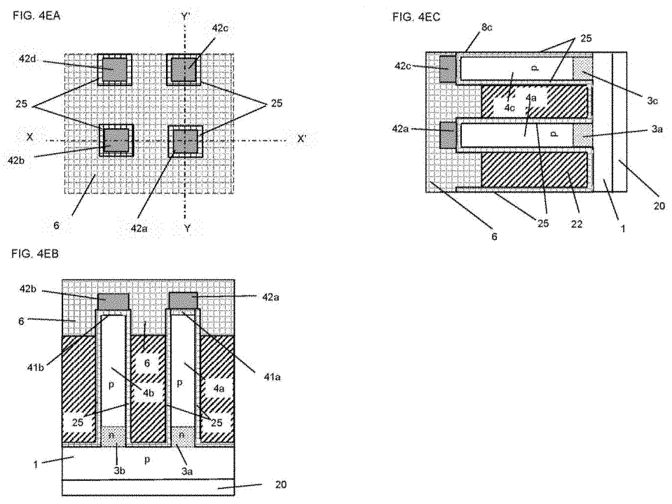

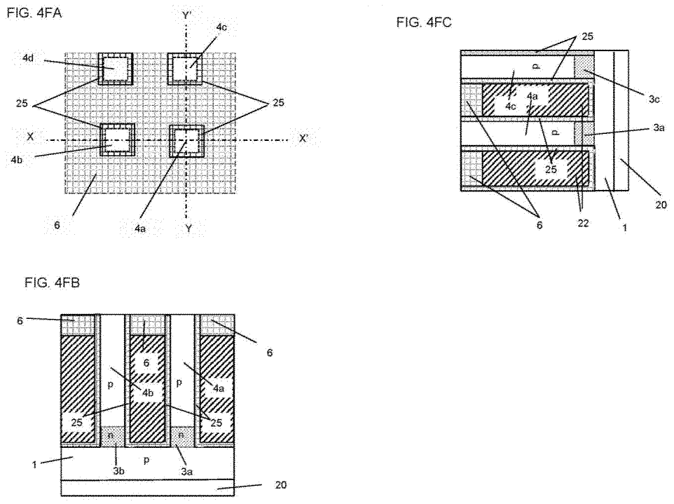

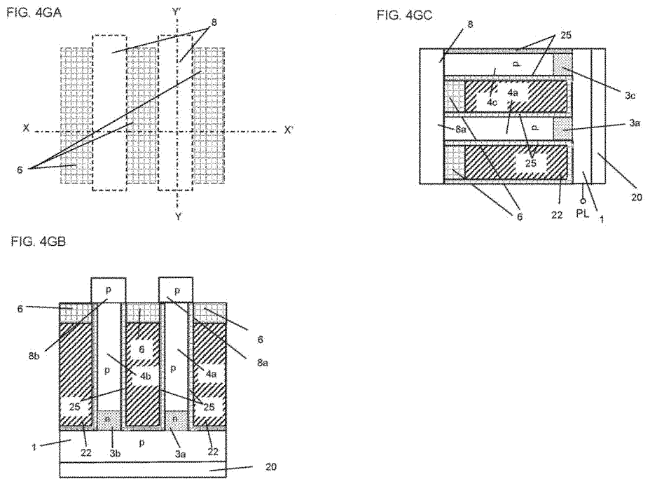

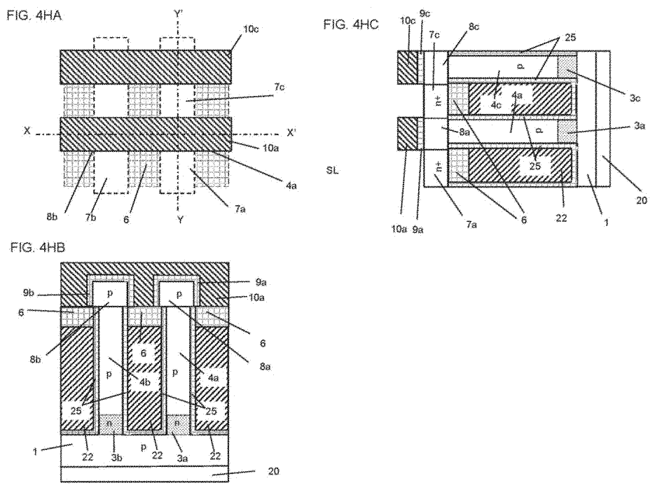

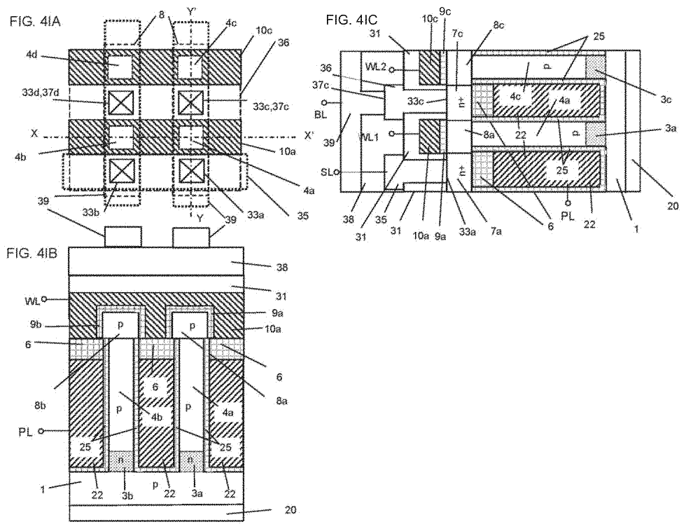

Referring to FIG. 4AA to FIG. 4IC, a method for producing the dynamic flash memory according to this embodiment will be described. In each of the drawings, the suffix A denotes a plan view, the suffix B denotes a vertical sectional view taken along line X-X′ in the drawing denoted by the suffix A, and the suffix C denotes a vertical sectional view taken along line Y-Y′ in the drawing denoted by the suffix A. Elements that are the same as or similar to those in FIG. 1 are denoted by reference signs including the same numeral signs as in FIG. 1.

As illustrated in FIGS. 4AA to 4AC, on a substrate 20, in ascending order, a p layer 1, an n layer 3, a p layer 4, an insulating layer 41, and a mask material layer 42 are formed. Note that the substrate may be a semiconductor or an insulating film. The p layer 1 and the n layer 3 may be well layers. The insulating layer 41 may be a silicon oxide film, for example. The mask material layer 42 may be a silicon nitride film, for example.

Subsequently, as illustrated in FIGS. 4BA to 4BC, in the regions that are to serve as memory cells, the insulating layer 41, the p layer 4, and the n layer 3 are etched by an RIE (Reactive Ion Etching) process through mask material layers 42a to 42d serving as masks. Note that, in FIGS. 4BB and 4BC, the bottom of the groove formed by the etching is illustrated at the same level as the bottom portion of the n layer 3; however, as long as the bottom of the groove is positioned deeper than the upper portion of the n layer 3, the bottom of the groove may be positioned shallower or deeper than the bottom portion of the n layer 3.

Subsequently, as illustrated in FIGS. 4CA to 4CC, on the side walls of the p layer 4 and the n layer 3 and the bottom portions provided by the etching, an insulating film 2 is selectively formed by oxidation. In FIGS. 1 to 3B, the gate insulating layer 5 and the insulating film 2 are separately illustrated; however, hereafter, these will be collectively illustrated as a gate insulating layer 25. For example, the ALD (Atomic Layer Deposition) technique may be used to form an oxide film over the entire structure (not shown). In this case, the gate insulating layer 25 is formed also around the mask material layer 42.

Subsequently, as illustrated in FIGS. 4DA to 4DC, polycrystalline silicon doped with boron at a high concentration is deposited as a gate conductor layer 22, by, for example, a CVD process over the entire surface; subsequently, etch-back is performed by a selective RIE process such that the upper surface of the gate conductor layer 22 is etched to a position lower than the upper surface of the p layer 4.

Subsequently, as illustrated in FIGS. 4EA to 4EC, for example, a CVD process is performed to form an insulating layer 6 over the entire surface.

Subsequently, as illustrated in FIGS. 4FA to 4FC, a CMP (Chemical Mechanical Polishing) technique is used to polish the insulating layer 6 until the surfaces of the mask materials 42a to 42d are exposed; furthermore, the mask materials 42a to 42d are selectively removed. Furthermore, the insulating layer 6 is subjected to etch-back until the surface of the p layer 4 is exposed; simultaneously, the insulating layer 41 is etched.

Subsequently, as illustrated in FIGS. 4GA to 4GC, a semiconductor layer 8 is grown by, for example, a CVD process under conditions so as to form crystalline layers continuously from the p layer 4; subsequently, in the memory cells, regions not necessary for operations as MOSFETs are removed.

Subsequently, as illustrated in FIGS. 4HA to 4HC, a gate insulating layer 9 is formed; a gate conductor layer 10 is formed of n+ poly having a lower work function than the gate conductor layer 22, and processed into gate electrodes of MOSFETs in the memory cells. These are illustrated, in FIGS. 4HA to 4HC, gate insulating layers 9a, 9b, and 9c and gate conductor layers 10a and 10c. Subsequently, an n+ layer 7a and an n+ layer 7b are formed in a self-alignment manner.

Subsequently, as illustrated in FIGS. 4IA to 4IC, an insulating layer 31 is formed over the entire surface; in the memory cells, contact holes 33a to 33d are formed. Subsequently, wiring conductor layers 35 and 36 are formed. The wiring conductor layer 35 is connected to a source line SL. Subsequently, an insulating film 38 is formed; subsequently, second contact holes 37c and 37d are formed and a wiring conductor layer 39 is formed. This is connected to a bit line BL.

For the plan view of FIG. 4IA, the actual upper region has the second wiring conductor layer 39 and the insulating film 38 alone; however, in order to aid ready understanding, main elements of lower layer regions that are the p layers 4a to 4d, the gate conductor layers 10a and 10c, and the contact holes 33a, 33b, 33c, 33d, 37c, and 37d are illustrated. With focus on the memory cell disposed at the point of intersection of X-X′ and Y-Y′ in FIG. 4IC, the correspondence of the main elements between FIG. 4IC and FIG. 1 is as follows: n layer 3 (FIG. 1)/n layer 3a (FIG. 41) (hereafter, similarly described), p layer 4/p layer 4a, semiconductor layer 8/semiconductor layer 8a, n+ layer 7a connecting to SL/n+ layer 7a connecting to SL, n+ layer 7b connecting to BL/n+ layer 7c connecting to BL, gate insulating layer 9/gate insulating layer 9a, gate conductor layer 10 connecting to WL/gate conductor layer 10a connecting to WL, and gate conductor layer 22 connecting to PL/gate conductor layer 22 connecting to PL.

This embodiment has been described with reference to the case where the impurity layer 4 is of a p-type, the gate conductor layer 22 is made of p+ poly, and the gate conductor layer 10 is made of n+ poly; as long as the gate conductor layer 22 has a work function higher than the work function of the gate conductor layer 10, for example, a combination such as p+ poly (5.15 eV)/laminated layer of W and TiN (4.7 eV), p+ poly (5.15 eV)/laminated layer of silicide and n+ poly (4.05 eV), or TaN (5.43 eV)/laminated layer of W and TiN (4.7 eV) may be employed. When the impurity layer 4 is of an n-type, as long as the gate conductor layer 22 has a work function lower than the work function of the gate conductor layer 10, for example, the gate conductor layer 22 can be formed of n+ poly and the gate conductor layer 10 can be formed of p+ poly, to provide similar advantages. Note that the gate conductor layers 10 and 22 may be semiconductors, metals, or compounds thereof.

For FIGS. 4BB to 4IC, the grooves having rectangular vertical sectional shapes have been described; alternatively, the vertical sectional shapes may be trapezoidal.

In this embodiment, the impurity layer 3 and the impurity layer 4 are illustrated as having pillar shapes having quadrangular bottom surfaces; alternatively, the layers may have pillar shapes having bottom surfaces having polygonal shapes other than quadrangles or circular shapes.

The n layer 3 is present at least in regions where memory cells are to be formed. Thus, although, in FIGS. 4AB and 4AC, the n layer 3 is illustrated as being formed over the entire surface of the p layer 1, the n layer 3 may be formed only in selected regions on the p layer 1.

Any materials may be employed for the mask material layers 42a to 42d and the gate insulating layer 25 as long as a selectivity ratio is provided during etching.

In FIGS. 4FA to 4FC, the endpoint material in CMP is the mask material layers 42a to 42d, but may alternatively be the gate insulating layer 25, the insulating layer 6, or the p layer 4, for example.

For the gate insulating layer 25 and the gate insulating layer 8 (9a to 9d), any insulating films used in ordinary MOS processes can be used, such as SiO₂ films, SiON films, HfSiON films, SiO₂/SiN laminated films.

For connection to the BL line, the method of separately forming the wiring conductor layer 36 and the wiring conductor layer 39 has been described; alternatively, for example, a damascene process can be performed to form the wiring conductor layers 36 and 39 and the contact holes 33c and 37c in one process.

In FIGS. 4AA to 4IA, the gate conductor layer 10, the semiconductor layer 8, and all the wiring conductor layers are illustrated as extending parallel to or perpendicular to the X-X′ axis or the Y-Y′ axis; alternatively, the layers may extend in oblique directions.

In this embodiment, MOS circuit regions including peripheral circuits other than the memory cells are not described; however, clearly, for such regions, the same masks as in regions of the p layer 8 in FIGS. 4GA to 4GC can be used and the impurity concentrations can be individually controlled, so that, after formation of the MOSFETs, the same process can be performed to thereby form MOSFETs for circuits other than the memory cells.

This embodiment has the following features.

### Feature 1

In the dynamic flash memory according to the first embodiment of the present invention, the substrate region where the channel of the MOSFET is formed is constituted by the p layer 4 surrounded by the insulating layer 2, the gate insulating layer 5, and the n layer 3, and the p layer 8. In this structure, the majority carriers generated during writing of logical data “1” can be stored in the p layer 8 and the p layer 4 and the number of the carriers can be increased. Furthermore, the gate conductor layer 22 is made of a material having a higher work function than the gate conductor layer 10, so that holes generated during writing can be stored in interface regions of the p layer 4, the interface regions being near the gate conductor layer 22, and the information retention time can be increased. During data erasing, a positive voltage is applied to the gate conductor layer 22 to form an inversion layer, so that the area of hole-electron recombination is effectively increased, to increase the area of recombination with electrons, which results in erasing in a short time. Therefore, the memory operation margin can be increased and power consumption can be reduced, which leads to memory high-speed operations.

### Feature 2

The p layer 8, which is one of elements of a MOSFET in the dynamic flash memory according to the first embodiment of the present invention, is connected to the p layer 4, the n layer 3, and the p layer 1; furthermore, the voltage applied to the gate conductor layer 22 is adjusted, so that the p layer 8 and the p layer 4 under the gate insulating layer 9 are not fully depleted. Thus, the threshold, the driving current, and the like of the MOSFET are less likely to be affected by the memory operation state. Furthermore, the region under the MOSFET is not fully depleted, so that the drawback of capacitor-less DRAMs that is, in the floating body, coupling of the gate electrode due to the word line does not considerably affect the MOSFET. Therefore, in the present invention, the dynamic flash memory can be designed so as to have an increased margin of the operation voltages.

### Feature 3

The p layer 8, which is one of elements of a MOSFET in the dynamic flash memory according to the first embodiment of the present invention, is connected to the p layer 4, and the amount of holes stored during writing of information data “1” can be increased by 10 times or more relative to, for example, the existing zero-capacitor DRAMs (M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010), and Takashi Ohasawa and Takeshi Hamamoto, “Floating Body Cell —a Novel Body Capacitorless DRAm Cell”, Pan Stanford Publishing (2011)). Thus, even when disturbances occur in voltages applied to memory cells that are not the target of reading or writing, the data of written information data “1” is less likely to be erased. For information data “0” written in a memory, even when disturbances occur in voltages applied to memory cells that are not the target of reading or writing and holes are unintentionally formed in the memory cells, the amount of holes generated is not large enough to change the information to “1” in a short time. As a result, the present invention provides a memory cell structure that is highly resistant to the disturb failure.

### Feature 4

The MOSFET of a cell has a structure in which the gate electrode surrounds the p layer 8, to provide an effective channel width that is large, so that the amount of excess holes during writing can be increased and the cell current can be increased, which enables memory high-speed operations.

### Feature 5

In the dynamic flash memory cells in FIG. 4IC, the n+ layer 7a, the wiring conductor layer 35 connected to the source line SL, and the contact hole 33a are shared by the adjacent cells. The n+ layer 7c, the wiring conductor layers 36 and 39 connected to the bit line BL, and the contact holes 33c and 37c are shared by the adjacent cells. Thus, the cell area of the dynamic flash memory according to this embodiment of the present invention is governed by the line and space of the p layers 8a and 8b and the line and space of the gate conductor layers 10a and 10c, or the line and space of the wiring conductor layers 35 and 36. Therefore, when the minimum dimension during production is defined as F, the cell area is 4F² and fine memory cells can be provided.

### Second Embodiment

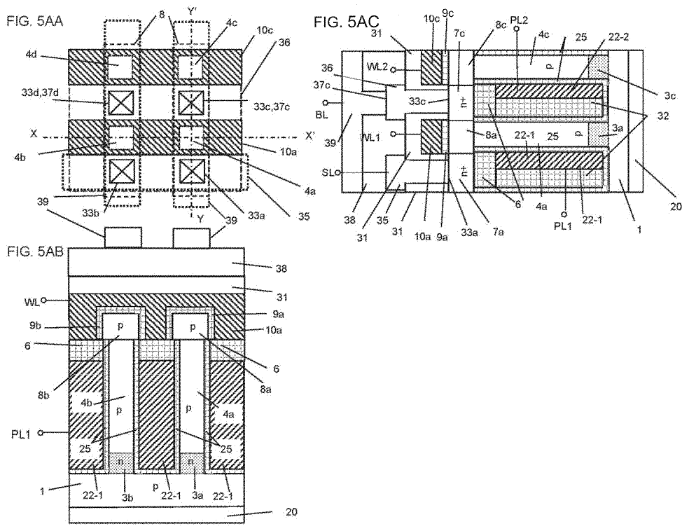

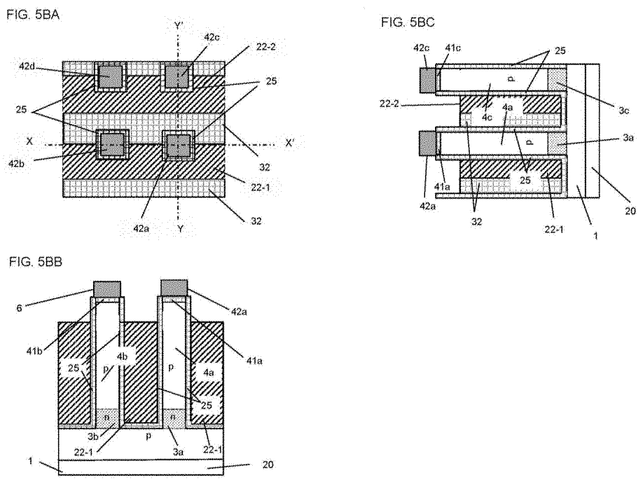

Referring to FIGS. 5AA to 5BC, a dynamic flash memory according to a second embodiment of the present invention will be described. In FIGS. 5AA to 5BC, elements that are the same as or similar to those in FIG. 1 and FIGS. 4AA to 4IC are denoted by reference signs including the same numeral signs as in FIG. 1 and FIGS. 4AA to 4IC.

As illustrated in FIG. 5AC, the gate conductor layer 22 in FIG. 4IC is electrically divided, by an insulating film 32 (serving as an example of “fourth insulating layer” in Claims), into gate conductor layers 22-1 and 22-2. Thus, the plate line is divided into PL1 (serving as an example of “first plate line” in Claims) connecting to the gate conductor layer 22-1 and PL2 (serving as an example of “second plate line” in Claims) connecting to the gate conductor layer 22-2. Thus, different voltages can be applied to PL1 and PL2. FIG. 5AA is a plan view of the structure and FIG. 5AC is a vertical sectional view taken along line Y-Y′. Also in such a structure, as in the first embodiment, voltages are applied to the source line SL, the plate lines PL-1 and PL-2, the word line WL, and the bit line BL to thereby operate the dynamic flash memory.

Referring to FIGS. 5BA to 5BC, an example of the production method will be described. FIGS. 5BA to 5BC illustrate a state in which, after the process in FIGS. 4DA to 4DC is complete, the lithography and etching techniques ordinarily used are used to etch a portion of the gate conductor layer 22 to form a groove and an insulating film 32 is formed in the groove. Subsequently, the same processes as in FIG. 4EA to 4IC can be performed to form the cell structure in FIGS. 5AA to 5AC.

FIGS. 5BA to 5BC illustrate sectional views and a plan view of an intermediate state during the production. FIGS. 5BA to 5BC illustrate a state in which the lithography and etching techniques ordinarily used are used to form a groove between the gate conductor layers 22-1 and 22-2 and in a portion of the gate conductor layer 22, and the insulating layer 32 is formed in the groove. Subsequently, the production proceeds directly to the process of FIGS. 4EA to 4EC and, during formation of the insulating layer 6, the groove is simultaneously filled. It is clear that the deposition of the insulating layer 6 can be performed also as the deposition of the insulating layer 32; in this case, the insulating layer 6 and the insulating layer 32 are formed of the same material.

For the dynamic flash memory according to the second embodiment of the present invention, voltage control during the reading operation will be described. Let us consider a case of reading information connecting to WL1. For example, in the case of applying 1 V to WL1, 0.5 V to BL, 1 V to PL1, 0 V to PL2, and 0 V to SL, the threshold of the MOS transistor connected to WL2 is about 0.4 V higher than in the MOS transistor connected to WL1. This can clearly be controlled using the voltages applied to PL1 and PL2. As a result of this control of the threshold, in spite of operation of WL1, the MOSFET connecting to WL2 has high effective threshold and substantially does not operate; thus, the effect of the disturbance can be reduced, and the disturb failure described in the first embodiment can be considerably addressed.

Note that FIG. 5AC illustrates the example in which the gate conductor layer 22 is divided into two by the insulating layer 32; however, the point of division can be freely selected and a desired number of memory cells can be disposed within the same gate conductor layer.

For the insulating film 32, any insulating film used in ordinary MOS processes can be used, such as a SiO₂ film, a SiON film, a HfSiON film, or a SiO₂/SiN laminated film.

This embodiment according to the present invention has the following features.

### Feature 1

As in the first embodiment, voltages are applied to the source line SL, the word line WL, and the bit line BL, and voltages are independently applied to the two plate lines PL-1 and PL-2, to thereby operate the dynamic flash memory. In the dynamic flash memory according to the second embodiment of the present invention, in the memory cell, the gate conductor layer 22-1 connecting to PL1 and the gate conductor layer 22-2 connecting to PL2 are electrically isolated and can be independently set at voltages. Therefore, the voltage applied to a PL electrode connecting to the target memory for reading or writing data information can be set differently from the voltage applied to the other PL electrode, so that the disturb failure described in the first embodiment can be further reduced.

### Feature 2

In the dynamic flash memory according to the second embodiment of the present invention, the PL electrode can be divided and the resultant electrodes can be individually controlled, so that the power consumed during the control can be reduced. Furthermore, the power generated during charging or discharging can be reused within the integrated circuit.

### Third Embodiment

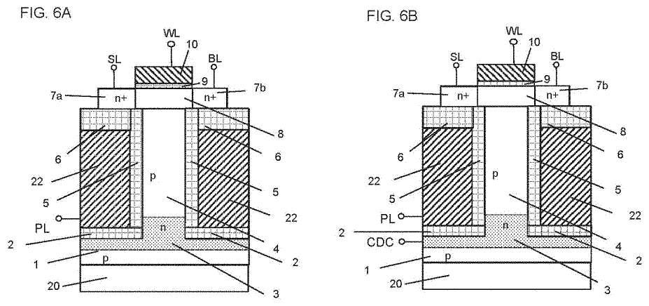

Referring to FIGS. 6A and 6B, a dynamic flash memory according to a third embodiment of the present invention will be described. In FIGS. 6A and 6B, elements that are the same as or similar to those in FIG. 1 are denoted by reference signs including the same numeral signs as in FIG. 1.

As illustrated in FIG. 6A, the bottom portion of the n layer 3 in FIG. 1 is positioned deeper than the gate insulating layer 2, and the n layer 3 is shared by a plurality of cells. The other configuration is the same as in FIG. 1. In this case, the gate insulating layer 2 may be in contact with or may not be in contact with the p layer 1. Also in this case, as in the first embodiment, voltages can be applied to the source line SL, the plate line PL, the word line WL, and the bit line BL to thereby operate the dynamic flash memory.

Referring to FIG. 6B, when the n layer 3 is shared by a plurality of cells, it can be connected to the control line CDC (serving as an example of “control line” in Claims) serving as the fifth wiring conductive layer and a voltage can be applied, to thereby simultaneously control a plurality of memory operations.

During writing of logical storage data “1”, in addition to the voltage application conditions of the first embodiment, for example, 1 V can be applied to CDC so as not to forward-bias the pn junction with the p layer 4, to suppress hole-electron recombination and to promote storage of holes.

When the storage data is erased to “0”, also in a case where, for example, 2 V is applied to the gate conductor layer 22, 1 V is applied to CDC, and the other potentials are set at 0 V, an inversion layer is formed in the interface between the p layer 4 and the gate insulating layer 5 in contact with the gate conductor layer 22, so that hole-electron recombination is promoted and loss of electrons due to the recombination is compensated for by supply of electrons from the n layer 3 and the n layers 7a and 7b, and hence holes stored in the memory cell can be rapidly discharged. In particular, the n layer 3 is shared by a plurality of cells, so that the operation of erasing information of multiple memory cells can be performed at a time. Thus, in the third embodiment, the margins of the writing operation of logical storage data “1” and the erase operation to “0” in the first embodiment can be further increased by controlling the voltage applied to CDC.

This embodiment has the following features.

### Feature 1

As in the first embodiment, voltages can be applied to the source line SL, the plate line PL, the word line WL, and the bit line BL to thereby operate the dynamic flash memory; furthermore, a voltage can be applied to the control line CDC, to thereby increase the operation margins of writing of storage information data “1” and erasing to “0”, and perform high-speed memory operations.

### Feature 2

The n layer 3 includes a plurality of cells and hence erasing to “0” can be achieved at a time for the plurality of cells.

For the present invention, without departing from the broad spirit and scope of the present invention, various embodiments and modifications can be made. The above-described embodiments are provided for the purpose of describing examples of the present invention and do not limit the scope of the present invention. The examples and modifications can be appropriately combined. In addition, the embodiments from which a portion of the features has been removed as needed also fall in the scope of the technical idea of the present invention.

Use of a semiconductor-element-including memory function according to the present invention can provide a dynamic flash memory that stores data for a longer time, consumes less power, and operates at higher speed than existing memories.

What is claimed is:

1. A semiconductor-element-including memory device comprising:
a substrate;
a first semiconductor region disposed on the substrate;
a first impurity region disposed on a portion of a surface of the first semiconductor region and including at least partially a pillar-shaped portion;
a second semiconductor region being in contact with the pillar-shaped portion of the first impurity region and extending in a vertical direction;
a first insulating layer covering a portion of the first semiconductor region and a portion of the first impurity region;
a first gate insulating layer being in contact with the first insulating layer and surrounding the first impurity region and the second semiconductor region;
a first gate conductor layer being in contact with the first insulating layer and the first gate insulating layer;
a second insulating layer formed so as to be in contact with the first gate conductor layer and the first gate insulating layer;
a third semiconductor region being in contact with the second semiconductor region;
a second gate insulating layer surrounding a portion or entirety of an upper portion of the third semiconductor region;
a second gate conductor layer covering a portion or entirety of an upper portion of the second gate insulating layer;
a second impurity region and a third impurity region being disposed outside of ends of the second gate conductor layer and being in contact with, in a horizontal direction in which the third semiconductor region extends, side surfaces of the third semiconductor region;
a first wiring conductor layer connecting to the second impurity region;
a second wiring conductor layer connecting to the third impurity region;
a third wiring conductor layer connecting to the second gate conductor layer; and
a fourth wiring conductor layer connecting to the first gate conductor layer, to form a memory cell.

2. The semiconductor-element-including memory device according to claim 1, wherein the first wiring conductor layer connecting to the second impurity region is a source line, the second wiring conductor layer connecting to the third impurity region is a bit line, the third wiring conductor layer connecting to the second gate conductor layer is a word line, the fourth wiring conductor layer connecting to the first gate conductor layer is a plate line, and the memory device is configured to apply voltages to the source line, the bit line, the plate line, and the word line to perform memory writing or erasing.

3. The semiconductor-element-including memory device according to claim 1, wherein a work function of the first gate conductor layer is different from a work function of the second gate conductor layer.

4. The semiconductor-element-including memory device according to claim 3, wherein the majority carrier of the first impurity region is electrons, the majority carrier of the second semiconductor region is holes, and the work function of the first gate conductor layer is higher than the work function of the second gate conductor layer.

5. The semiconductor-element-including memory device according to claim 3, wherein the majority carrier of the first impurity region is holes, the majority carrier of the second semiconductor region is holes, and the work function of the first gate conductor layer is lower than the work function of the second gate conductor layer.

6. The semiconductor-element-including memory device according to claim 1, wherein the majority carrier of the first impurity region is different from a majority carrier of the first semiconductor region.

7. The semiconductor-element-including memory device according to claim 1, wherein the majority carrier of the second semiconductor region is the same as a majority carrier of the first semiconductor region.

8. The semiconductor-element-including memory device according to claim 1, wherein majority carriers of the second impurity region and the third impurity region are the same as the majority carrier of the first impurity region.

9. The semiconductor-element-including memory device according to claim 1, wherein the first impurity region has a lower concentration than the second impurity region and the third impurity region.

10. The semiconductor-element-including memory device according to claim 1, wherein a vertical distance from a bottom portion of the third semiconductor region to an upper portion of the first impurity region is shorter than a vertical distance from a bottom portion of the third semiconductor region to a bottom portion of the first gate conductor layer.

11. The semiconductor-element-including memory device according to claim 2, wherein a source-line contact hole for connection between the source line and the second impurity region and the first wiring conductor layer are shared by adjacent memory cells.

12. The semiconductor-element-including memory device according to claim 2, wherein a bit-line contact hole for connection between the bit line and the third impurity region and the second wiring conductor layer are shared by adjacent memory cells.

13. The semiconductor-element-including memory device according to claim 1, wherein a fourth insulating layer in contact with the first gate conductor layer divides the first gate conductor layer into two layers, the two layers are individually connected to a first plate line and a second plate line, and the first plate line and the second plate line are configured to be independently subjected to application of voltages.

14. The semiconductor-element-including memory device according to claim 13, comprising a plurality of memory cells in contact with the first plate line and a plurality of memory cells in contact with the second plate line, wherein each of the memory cells is not in contact with both of the first plate line and the second plate line.

15. The semiconductor-element-including memory device according to claim 1, wherein the first impurity region has a bottom portion positioned deeper than a bottom portion of the first insulating layer, and the first impurity region is shared by a plurality of memory cells.

16. The semiconductor-element-including memory device according to claim 1, wherein the first impurity region is shared by a plurality of memory cells and the plurality of memory cells are configured to simultaneously perform an erase operation.

17. The semiconductor-element-including memory device according to claim 12, comprising a fifth wiring conductor layer connecting to the first impurity region, wherein the fifth wiring conductor layer is a control line and is configured to be subjected to application of a desired voltage.

18. The semiconductor-element-including memory device according to claim 1, wherein the memory device is configured to control voltages applied to the first wiring conductor layer, the second wiring conductor layer, the third wiring conductor layer, and the fourth wiring conductor layer to perform an operation of using a current flowing between the second impurity region and the third impurity region to cause an impact ionization phenomenon or using a gate induced drain leakage current, to generate an electron group and a hole group in the third semiconductor region and the second semiconductor region, an operation of discharging, of the generated electron group and hole group, the electron group or hole group serving as a minority carrier in the third semiconductor region and the second semiconductor region, and an operation of causing a portion or entirety of the electron group or hole group serving as a majority carrier in the third semiconductor region and the second semiconductor region to remain in the third semiconductor region and the second semiconductor region, to perform a memory write operation, and
the memory device is configured to control voltages applied to the first wiring conductor layer, the second wiring conductor layer, the third wiring conductor layer, and the fourth wiring conductor layer to remove, from at least one of the first impurity region, the second impurity region, or the third impurity region, the electron group or hole group remaining and serving as a majority carrier in the second semiconductor region or the third semiconductor region by recombination with a majority carrier of the first impurity region, the second impurity region, or the third impurity region, to perform a memory erase operation.
